(19) United States
(12) Patent Application Publication
(10) Pub. No.: US 2026/0140403 A1
(43) Pub. Date: May 21, 2026

(54) OPTICAL SEMICONDUCTOR DEVICE

(71) Applicant: Mitsubishi Electric Corporation, Tokyo (JP)

(72) Inventors: Kyosuke KURAMOTO, Tokyo (JP); Eitaro ISHIMURA, Tokyo (JP)

(73) Assignee: Mitsubishi Electric Corporation, Tokyo (JP)

(21) Appl. No.: 19/299,310

(22) Filed: Aug. 13, 2025

(30) Foreign Application Priority Data
Nov. 20, 2024 (JP) 2024-202683

(51) Int. Cl. G02F 1/015

(52) U.S. Cl. CPC G02F 1/0155

(57) ABSTRACT

An optical semiconductor device includes: a substrate; an optical modulator including a semiconductor layer having a first conductivity type layer, an absorbing layer and a second conductivity type layer which are formed in this order on the substrate, a first electrode connected to the first conductivity type layer, and a second electrode connected to the second conductivity type layer; a first pad connected to the first electrode; and a second pad connected to the second electrode, wherein the semiconductor layer includes a waveguide, a first terrace and a second terrace positioned on opposite sides with respect to the waveguide, the first pad and the second pad are placed on the first terrace via an insulating film, and the first conductivity type layer is removed in the first terrace between the first pad and the second pad.

### BACKGROUND OF THE INVENTION

### Field

The present disclosure relates to an optical semiconductor device.

### BACKGROUND

An optical semiconductor device in which a laser unit and an optical modulator are monolithically integrated has been proposed (see, for example, Patent Literature 1). The optical modulator is differentially operated by the differential voltage applied between an anode pad and a cathode pad. The anode pad and the cathode pad of the optical modulator are placed on a terrace on the same side with respect to a waveguide, which makes it possible to equalize the lengths of wires connected to both of the pads.

### CITATION LIST

### Patent Literature

Patent Literature 1: JP 5891920 B2

### SUMMARY

When the optical modulator is differentially operated, a leakage current flows between the two pads of the optical modulator, which causes a decrease in the voltage applied to an absorbing layer of the optical modulator. The leakage current flows through a capacitance under the electrodes of the optical modulator, and, therefore, as the frequency increases, the leakage current increases and the extinction ratio decreases. As a result, there is a problem of reduction of the frequency band in which the optical modulator can operate normally.

The present disclosure has been made to solve the problem mentioned above, and the purpose of the disclosure is to obtain an optical semiconductor device capable of preventing a reduction of the frequency band.

### Solution to Problem

An optical semiconductor device according to the present disclosure includes: a substrate; an optical modulator including a semiconductor layer having a first conductivity type layer, an absorbing layer and a second conductivity type layer which are formed in this order on the substrate, a first electrode connected to the first conductivity type layer, and a second electrode connected to the second conductivity type layer; a first pad connected to the first electrode; and a second pad connected to the second electrode, wherein the semiconductor layer includes a waveguide, a first terrace and a second terrace positioned on opposite sides with respect to the waveguide, the first pad and the second pad are placed on the first terrace via an insulating film, and the first conductivity type layer is removed in the first terrace between the first pad and the second pad.

### Advantageous Effects of Invention

In the present disclosure, the first conductivity type layer is removed in the first terrace between the first pad and the second pad. Therefore, the leakage current path between the first pad and the second pad is split and the leakage current is reduced, which improves the response particularly in a high frequency range. As a result, a reduction of the frequency band can be prevented.

### BRIEF DESCRIPTION OF DRAWINGS

FIG. 1 is a top view showing an optical semiconductor device according to a first embodiment.

FIG. 2 is a cross-sectional view of the laser unit taken along A-A′ in FIG. 1.

FIG. 3 is a cross-sectional view of the optical modulator taken along B-B′ in FIG. 1.

FIG. 4 is a cross-sectional view of the optical modulator taken along C-C′ in FIG. 1.

FIG. 5 is a cross-sectional view of the waveguide taken along D-D′ in FIG. 1.

FIG. 6 is a cross-sectional view of the first terrace taken along E-E′ in FIG. 1.

FIG. 7 is a top view showing an optical semiconductor device according to the comparative example.

FIG. 8 is a cross-sectional view of the waveguide taken along A-A′ in FIG. 7.

FIG. 9 is a cross-sectional view of the first terrace taken along B-B′ in FIG. 7.

FIG. 10 is a diagram showing the frequency response characteristics of the first embodiment and the comparative example.

FIG. 11 is a top view showing an optical semiconductor device according to a second embodiment.

FIG. 12 is a cross-sectional view of an optical modulator taken along A-A′ in FIG. 11.

FIG. 13 is a cross-sectional view of the optical modulator taken along B-B′ in FIG. 11.

### DESCRIPTION OF EMBODIMENTS

An optical semiconductor device according to the embodiments of the present disclosure will be described with reference to the drawings. The same components will be denoted by the same symbols, and the repeated description thereof may be omitted.

### First Embodiment

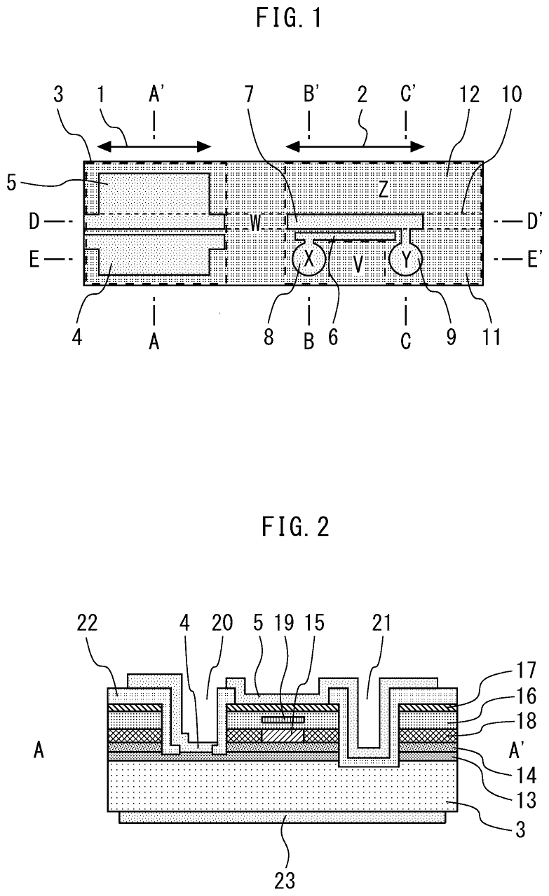

FIG. 1 is a top view showing an optical semiconductor device according to a first embodiment. This optical semiconductor device is a modulator-integrated laser diode in which a laser unit 1 and an optical modulator 2 are monolithically integrated on a semi-insulating InP substrate 3. The laser unit 1 is a distributed-feedback laser diode (DFB-LD). The optical modulator 2 is an electro-absorption modulator.

The laser unit 1 includes a cathode electrode 4 and an anode electrode 5. The optical modulator 2 includes a cathode electrode 6 and an anode electrode 7. A cathode pad 8 is connected to the cathode electrode 6. An anode pad 9 is connected to the anode electrode 7. The optical modulator 2 is differentially operated by the differential voltage applied between the cathode pad 8 and the anode pad 9.

A first terrace 11 and a second terrace 12 are positioned on opposite sides with respect to a waveguide 10. The cathode pad 8 and the anode pad 9 are placed on the first terrace 11. This makes it possible to equalize the lengths of a wire connected to the anode pad 9 and a wire connected to the cathode pad 8.

A region V in the figure is a region between the cathode pad 8 and the anode pad 9. A region W is a region between the laser unit 1 and the optical modulator 2. A region X is a region in which the cathode pad 8 is formed. A region Y is a region in which the anode pad 9 is formed. A region Z is a region in which the second terrace 12 of the optical modulator 2 is present. A region surrounded by a wavy line in the figure is a region in which an n-type cladding layer and an n-type contact layer as described below are present.

FIG. 2 is a cross-sectional view of the laser unit taken along A-A′ in FIG. 1. An n-InGaAs contact layer 13, an n-InP cladding layer 14, an active layer 15, a p-InP cladding layer 16, and a p-InGaAs contact layer 17 are stacked in this order on the semi-insulating InP substrate 3. The active layer 15 has an InGaAsP multi-quantum well (MQW) structure.

The active layer 15 is patterned into stripes in a plan view, and both sides are embedded in an Fe-InP block layer 18. A diffraction grating 19 is formed in the p-InP cladding layer 16.

On both sides of the active layer 15, a first groove 20 and a second groove 21 are formed in the p-InGaAs contact layer 17, the p-InP cladding layer 16, the Fe—InP block layer 18, and the n-InP cladding layer 14. The second groove 21 is formed up to a position below the n-InGaAs contact layer 13. The upper surface of the p-InGaAs contact layer 17 and the inner surfaces of the first groove 20 and the second groove 21 are covered with an insulating film 22. An opening is formed in the insulating film 22 above a mesa structure between the first groove 20 and the second groove 21, and the anode electrode 5 is connected to the p-InGaAs contact layer 17 through this opening. An opening is formed in the insulating film 22 on the bottom surface of the first groove 20, and the cathode electrode 4 is connected to the p-InGaAs contact layer 17 through this opening. An n-electrode 23 is formed on the lower surface of the semi-insulating InP substrate 3.

In order to connect the cathode electrode 4 of the laser unit 1 to the active layer 15 of the laser unit 1 with low resistance, the low-resistance n-InP cladding layer 14 and n-InGaAs contact layer 13 are needed for a connection portion between below the active layer 15 of the waveguide 10 of the laser unit 1 and the cathode electrode 4 of the laser unit 1. In particular, the n-InGaAs contact layer 13 has a very low resistance.

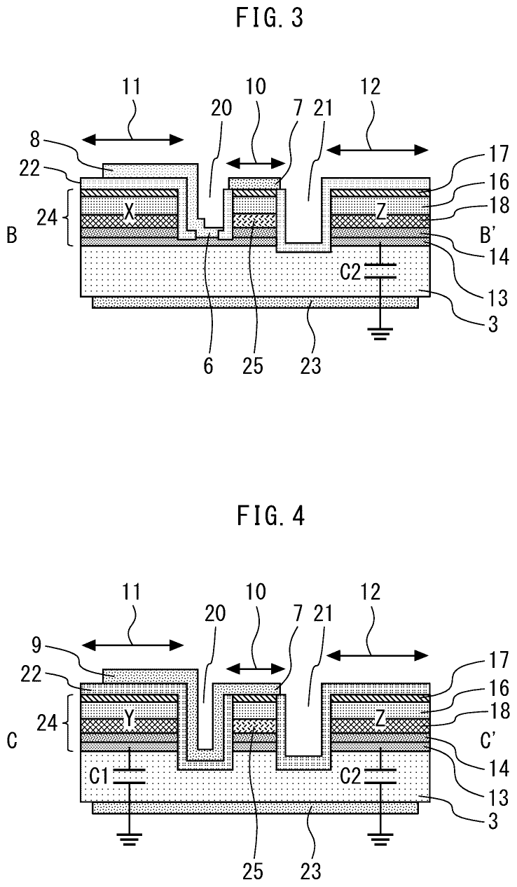

FIG. 3 is a cross-sectional view of the optical modulator taken along B-B′ in FIG. 1. As a semiconductor layer 24, the n-InGaAs contact layer 13, the n-InP cladding layer 14, the p-InP cladding layer 16, and the p-InGaAs contact layer 17 are stacked in this order on the semi-insulating InP substrate 3. The first groove 20 and the second groove 21 are formed spaced apart from each other in the p-InGaAs contact layer 17, the p-InP cladding layer 16, and the n-InP cladding layer 14. The first groove 20 and the second groove 21 limit the lateral width of an absorbing layer 25 to cause the absorbing layer 25 to function as the waveguide 10. The absorbing layer 25 is formed between the n-InP cladding layer 14 and the p-InP cladding layer 16 within the mesa structure between the first groove 20 and the second groove 21. The absorbing layer 25 has an InGaAsP multi-quantum well structure.

The semiconductor layer 24 includes the waveguide 10, the first terrace 11 and the second terrace 12 positioned on the opposite sides with respect to the waveguide 10. In the first terrace 11 and the second terrace 12, instead of the absorbing layer 25, the Fe—InP block layer 18 is formed between the n-InP cladding layer 14 and the p-InP cladding layer 16. An opening is formed in the insulating film 22 on the bottom surface of the first groove 20, and the cathode electrode 6 is connected to the n-InGaAs contact layer 13 through this opening. The cathode pad 8 is placed on the first terrace 11 via the insulating film 22, and connected to the cathode electrode 6. In order to electrically separate electrostatic capacitance C2 from the lower portion of the absorbing layer 25 of the optical modulator 2, the depth of the second groove 21 is made deeper than the n-InGaAs contact layer 13. On the other hand, in order to connect the cathode electrode 6 of the optical modulator 2 and the n-InGaAs contact layer 13, the depth of the first groove 20 in a connection portion between the cathode electrode 6 and the n-InGaAs contact layer 13 is set to the upper portion of the n-InGaAs contact layer 13. It is necessary to form these grooves having different depths in another process.

In order to connect the cathode electrode 6 of the optical modulator 2 to the absorbing layer 25 of the optical modulator 2 with low resistance, the low-resistance n-InP cladding layer 14 and n-InGaAs contact layer 13 are needed for a connection portion between below the absorbing layer 25 of the waveguide 10 of the optical modulator 2 and the cathode electrode 6 of the optical modulator 2. In particular, the n-InGaAs contact layer 13 has a very low resistance.

FIG. 4 is a cross-sectional view of the optical modulator taken along C-C′ in FIG. 1. Like the cathode pad 8, the anode pad 9 is placed on the first terrace 11 via the insulating film 22. An opening is formed in the insulating film 22 in the upper portion the waveguide 10. The anode electrode 7 is connected to the p-InGaAs contact layer 17 through the opening of the insulating film 22 in the upper portion of the waveguide 10, and connected to the anode pad 9 through the side surface and bottom surface of the first groove 20.

An electrostatic capacitance C1 is generated in the semi-insulating InP substrate 3 sandwiched between the n-InGaAs contact layer 13 and the n electrode 23 below the anode pad 9 of the first terrace 11. An electrostatic capacitance C2 is generated in the semi-insulating InP substrate 3 sandwiched between the n-InGaAs contact layer 13 and the n electrode 23 in the second terrace 12. In order to electrically separate the electrostatic capacitances C1 and C2 from the lower portion of the absorbing layer 25 of the optical modulator 2, the depths of the first groove 20 and the second groove 21 in portions through which the anode electrode 7 passes are made deeper than the n-InGaAs contact layer 13.

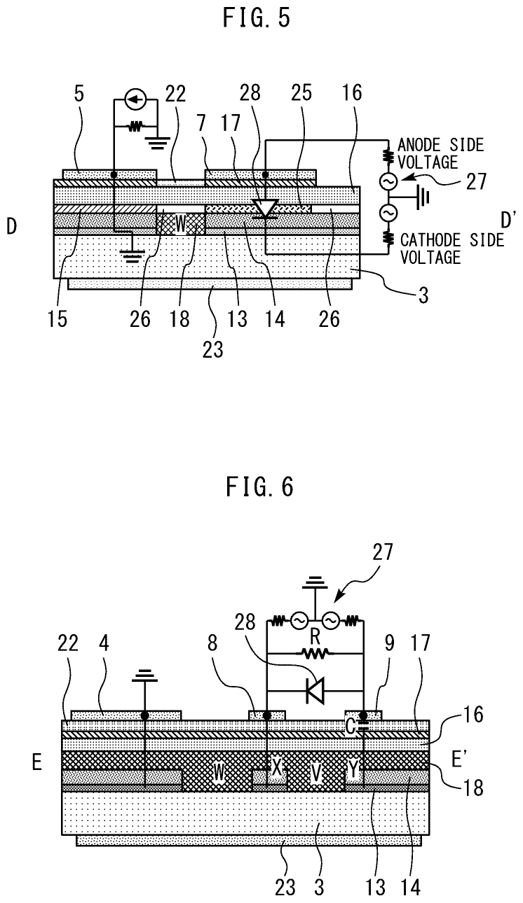

FIG. 5 is a cross-sectional view of the waveguide taken along D-D′ in FIG. 1. The active layer 15 and the absorbing layer 25 are connected by a transparent waveguide layer 26. The transparent waveguide layer 26 is also formed between the absorbing layer 25 and an emission end surface. The transparent waveguide layer 26 is made of an InGaAsP monolayer. The n-InP cladding layer 14 and the n-InGaAs contact layer 13 which are low resistance layers are removed in the waveguide 10 of the region W between the optical modulator 2 and the laser unit 1 and are embedded in the Fe—InP block layer 18. This causes the n-InGaAs contact layer 13 and the n-InP cladding layer 14 of the laser unit 1 to be electrically insulated from the n-InGaAs contact layer 13 and the n-InP cladding layer 14 of the optical modulator 2.

FIG. 6 is a cross-sectional view of the first terrace taken along E-E′ in FIG. 1. The cathode pad 8 and the anode pad 9 are each connected to a differential power supply 27. The differential power supply 27 performs a push-pull operation by alternately applying a positive voltage to one terminal and a negative voltage to the other terminal. Without limitation to this, the voltage on the anode side may be varied and the electric potential on the cathode side may be zero. A load resistor R is connected in parallel to a p-n junction 28 of the optical modulator 2. The load resistor R is provided outside the device for impedance matching.

The n-InP cladding layer 14 and the n-InGaAs contact layer 13 which are low resistance layers are removed in the region V between the cathode pad 8 and the anode pad 9 in the first terrace 11 and are embedded in the Fe—InP block layer 18. The n-InP cladding layer 14 and the n-InGaAs contact layer 13 which are low resistance layers are removed in the region W between the cathode pad 8 of the optical modulator 2 and the cathode electrode 4 of the laser unit 1 and are embedded in the Fe—InP block layer 18.

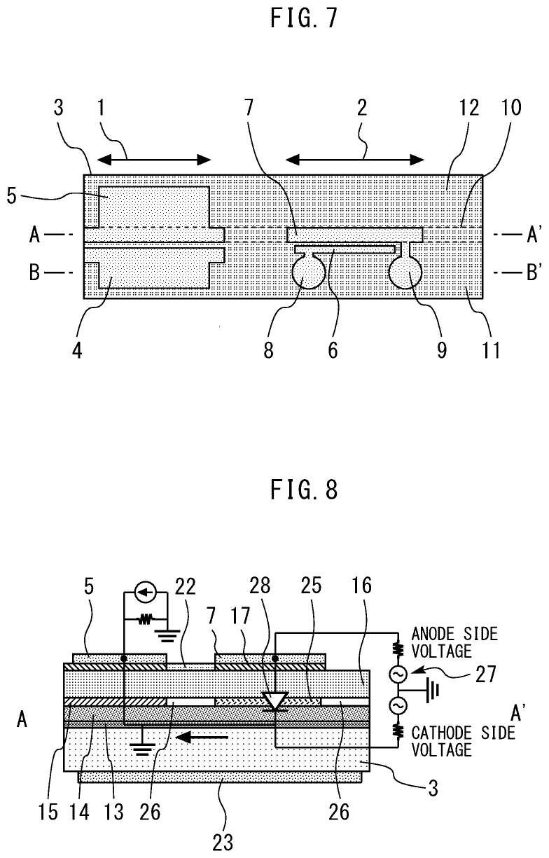

Next, the effect of the present embodiment will be described in comparison with a comparative example. FIG. 7 is a top view showing an optical semiconductor device according to the comparative example. FIG. 8 is a cross-sectional view of the waveguide taken along A-A′ in FIG. 7. In the comparative example, the n-InGaAs contact layer 13 and the n-InP cladding layer 14 are formed on the entire chip surface and are not removed. Since the n-InP cladding layer 14 and the n-InGaAs contact layer 13 which are low resistance layers are present in the waveguide 10 between the optical modulator 2 and the laser unit 1, a leakage current flows between the optical modulator 2 and the laser unit 1. Therefore, the amplitude of a voltage applied to the optical modulator 2 from the cathode side of the differential power supply 27 decreases, and the load impedances viewed from the anode side and cathode side of the differential power supply 27 are different. Furthermore, a part of the leakage current flows to the active layer 15 of the laser unit 1, so that an amount of current flowing in the active layer 15 is varied and light output of the laser unit 1 is varied. When the light output of the laser unit 1 is varied, the output of light after being modulated by the optical modulator 2 is also varied accordingly. Very large wavelength chirping (wavelength variation) also occurs. Thus, reducing the leakage current is important to improve the communication quality.

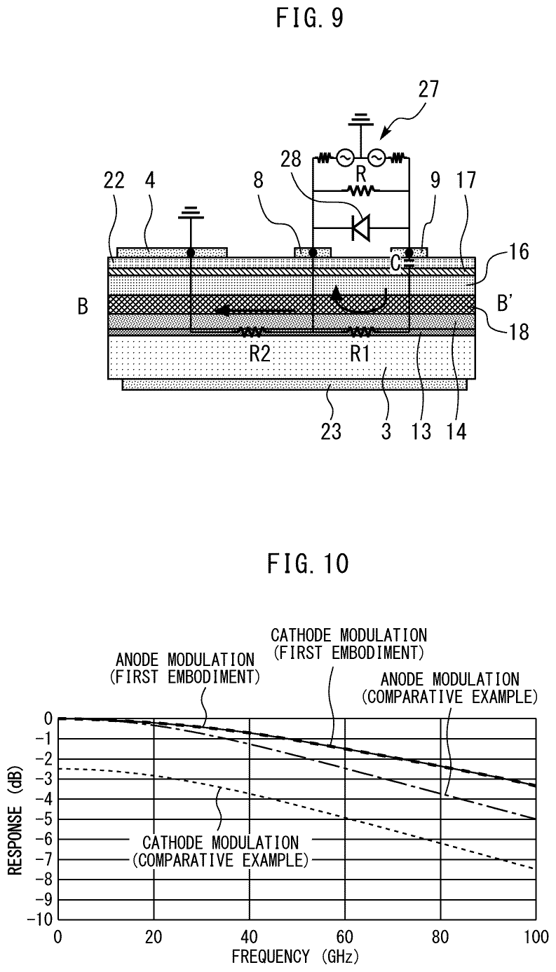

FIG. 9 is a cross-sectional view of the first terrace taken along B-B′ in FIG. 7. The cathode pad 8 and the anode pad 9 are high-frequency connected through the insulating film 22, the p-InP cladding layer 16, the Fe—InP block layer 18, the n-InP cladding layer 14, and the n-InGaAs contact layer 13. Therefore, a resistor R1 that is a leakage current path is present in the semiconductor layer 24 between the cathode pad 8 and the anode pad 9.

Moreover, the cathode pad 8 of the optical modulator 2 and the cathode electrode 4 of the laser unit 1 are also high-frequency connected in the same manner. Therefore, a resistor R2 that is a leakage current path is present in the semiconductor layer 24 between the anode pad 9 and the cathode electrode 4. Note that the positions of the cathode pad 8 and the anode pad 9 of the optical modulator 2 may be reversed. In this case, an electric potential difference occurs between the anode electrode 7 of the optical modulator 2 and the cathode electrode 4 of the laser unit 1, and a leakage current occurs.

A current caused by the anode voltage of the differential power supply 27 flows to each of a path passing through the load resistor R and the resistor R2, and a path passing through a capacitance C of the insulating film 22, the resistor R1 and the resistor R2. A current caused by the cathode voltage flows to the cathode electrode 4 of the laser unit 1 through the resistor R2.

The higher the frequency, the lower the impedance of the capacitance C, and the more the leakage current flows through the resistor R1. Since the current flowing through the load resistor R decreases due to the increase of the leakage current, the voltage to be applied to the optical modulator 2 decreases. Therefore, as the frequency increases, the leakage current increases, and the extinction ratio decreases, resulting in a reduction of the frequency band.

On the other hand, in the present embodiment, the n-InP cladding layer 14 and the n-InGaAs contact layer 13 are removed in the region V between the cathode pad 8 and the anode pad 9, so that the leakage current path is split and the leakage current is reduced, which improves the response particularly in a high frequency range. As a result, a reduction of the frequency band can be prevented. Note that it is only required that one of the n-InP cladding layer 14 and the n-InGaAs contact layer 13 is removed, but both are preferably removed. The same effect can also be obtained even in a semiconductor device including a single optical modulator without the laser unit 1 if the n-InP cladding layer 14 and the n-InGaAs contact layer 13 are removed between the pads.

Moreover, in the comparative example, since the resistors R1, R2 are present, the path of the current caused by the cathode voltage and the path of the current caused by the anode voltage are different, and the impedances of both are also different. On the other hand, in the present embodiment, since the n-InP cladding layer 14 and the n-InGaAs contact layer 13 are removed in the region V and the region W, which splits the paths of current flowing through the resistors R1 and R2, the current due to both voltages flows only through the load resistor R. Consequently, the impedance on the anode side and the impedance on the cathode side become equal. As a result, since the frequency response characteristics to the anode modulation and the cathode modulation become almost the same, it is possible to perform an ideal differential operation. The impedance on the anode side and the impedance on the cathode side are made equal to each other, so that the amplitude and phase of noise on the anode side can match those on the cathode side, and the noise reduction effect by the differential operation can be maximized.

FIG. 10 is a diagram showing the frequency response characteristics of the first embodiment and the comparative example. It can be understood that, in present embodiment, both of the frequency response to anode modulation and the frequency response to cathode modulation are improved compared to the comparative example.

### Second Embodiment

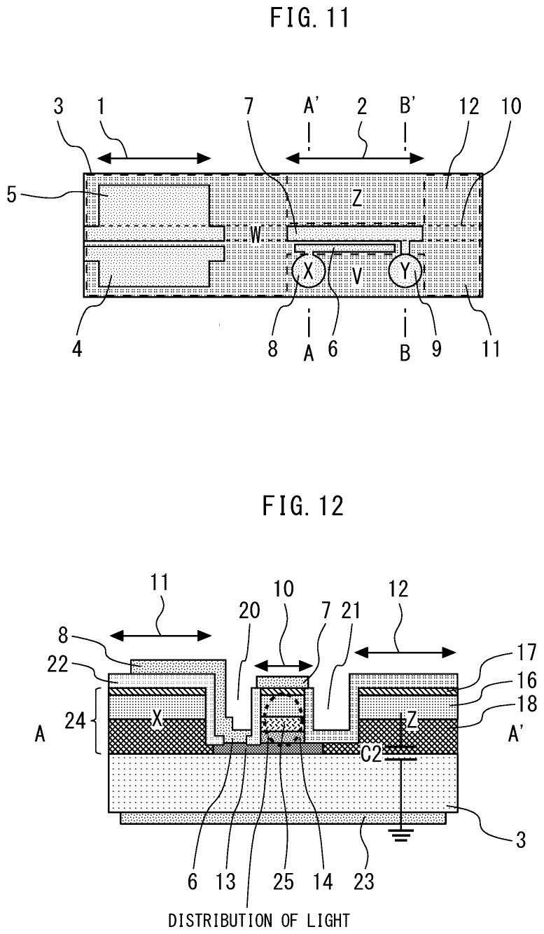

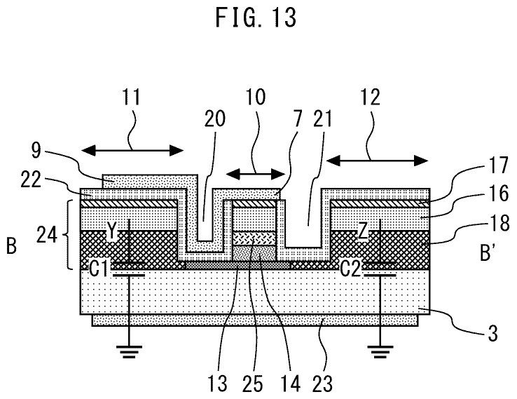

FIG. 11 is a top view showing an optical semiconductor device according to a second embodiment. FIG. 12 is a cross-sectional view of an optical modulator taken along A-A′ in FIG. 11. FIG. 13 is a cross-sectional view of the optical modulator taken along B-B′ in FIG. 11. In the present embodiment, an n-InP cladding layer 14 and an n-InGaAs contact layer 13 are removed in the entire region of a first terrace 11 and the entire region of a second terrace 12, of the optical modulator 2. In other regions, the n-InP cladding layer 14 and the n-InGaAs contact layer 13 are present. Note that also in the present embodiment, the n-InP cladding layer 14 and the n-InGaAs contact layer 13 may be removed in the region W in the same manner as in the first embodiment. The other configurations are the same as those in the first embodiment.

An electrostatic capacitance C1 is generated in the first terrace 11 between the n electrode 23 and the p-InP cladding layer 16 which sandwiches the Fe—InP block layer 18 with the semi-insulating InP substrate 3. Note that in the first terrace 11, the n-InP cladding layer 14 and the n-InGaAs contact layer 13 are removed. Thus, the resistance between the n-InP cladding layer 14 and the n-InGaAs contact layer 13 of the waveguide 10 of the optical modulator 2 and the electrostatic capacitance C1 greatly increases. Therefore, it is unnecessary to make the bottom surface of a first groove 20 shown in FIG. 13 deeper than the n-InGaAs contact layer 13. In the same manner, an electrostatic capacitance C2 is generated in the second terrace 12 between the n electrode 23 and the p-InP cladding layer 16 which sandwiches the Fe—InP block layer 18 with the semi-insulating InP substrate 3. Note that in the second terrace 12, the n-InP cladding layer 14 and the n-InGaAs contact layer 13 are removed. Thus, the resistance between the n-InP cladding layer 14 and the n-InGaAs contact layer 13 of the waveguide 10 of the optical modulator 2 and the electrostatic capacitance C2 greatly increases. Therefore, it is unnecessary to make the bottom surface of a second groove 21 deeper than the n-InGaAs contact layer 13. When the n-InP cladding layer 14 and the n-InGaAs contact layer 13 are thus removed in the first terrace 11 and the second terrace 12 of the optical modulator 2, a problem of an increase of the electrostatic capacitances is not generated even when the depths of the first groove 20 and the second groove 21 are equalized.

In the first embodiment, as shown in FIG. 3, the depth of the first groove 20 and the depth of the second groove 21 are different in a connection portion between the cathode electrode 6 and the n-InGaAs contact layer 13. Therefore, a distribution of light guided in the optical modulator 2 is bilaterally asymmetrical. This causes a light scattering loss to be generated when laser light having a light distribution that is bilaterally symmetrical is guided in the optical modulator 2 or while the laser light is guided in the optical modulator 2. On the other hand, in the present embodiment, the depth of the first groove 20, the depth of the first groove 20 in a portion through which the anode electrode 7 passes, and the depth of the second groove 21 are the same in the connection portion between the cathode electrode 6 and the n-InGaAs contact layer 13. Therefore, a distribution of light guided in the optical modulator 2 becomes bilaterally symmetrical. This can reduce the light scattering loss when the laser light is guided in the optical modulator 2.

### Reference Signs List

1 laser unit; 2 optical modulator; 3 semi-insulating InP substrate (substrate); 4 cathode electrode (electrode); 6 cathode electrode (first electrode); 7 anode electrode (second electrode); 8 cathode pad (first pad); 9 anode pad (second pad); 10 waveguide; 11 first terrace; 12 second terrace; 13 n-InGaAs contact layer (first conductivity type layer); 14 n-InP cladding layer (first conductivity type layer); 16 p-InP cladding layer (second conductivity type layer); 20 first groove; 21 second groove; 22 insulating film; 24 semiconductor layer; 25 absorbing layer

Obviously many modifications and variations of the present disclosure are possible in the light of the above teachings. It is therefore to be understood that within the scope of the appended claims the invention may be practiced otherwise than as specifically described.

The entire disclosure of Japanese Patent Application No. 2024-202683, filed on Nov. 20, 2024 including specification, claims, drawings and summary, on which the convention priority of the present application is based, is incorporated herein by reference in its entirety.

1. An optical semiconductor device comprising:
a substrate;
an optical modulator including a semiconductor layer having a first conductivity type layer, an absorbing layer and a second conductivity type layer which are formed in this order on the substrate, a first electrode connected to the first conductivity type layer, and a second electrode connected to the second conductivity type layer;
a first pad connected to the first electrode; and
a second pad connected to the second electrode,
wherein the semiconductor layer includes a waveguide, a first terrace and a second terrace positioned on opposite sides with respect to the waveguide,
the first pad and the second pad are placed on the first terrace via an insulating film, and
the first conductivity type layer is removed in the first terrace between the first pad and the second pad.

2. The optical semiconductor device according to claim 1, further comprising a laser unit monolithically integrated on the substrate with the optical modulator,
wherein the first conductivity type layer is removed between the optical modulator and the laser unit.

3. The optical semiconductor device according to claim 1, wherein a first groove is formed between the waveguide and the first terrace and a second groove is formed between the waveguide and the second terrace in the semiconductor layer of the optical modulator,
the first electrode is connected to the first conductivity type layer at a bottom portion of the first groove,
the second electrode is connected to the second conductivity type layer at an upper portion of the waveguide and connected to the second pad through the first groove,
the first conductivity type layer is removed in the first terrace and the second terrace of the optical modulator, and
a depth of the first groove at a connection portion between the first electrode and the first conductivity type layer, a depth of the first groove in a portion through which the second electrode passes, and a depth of the second groove are the same.

4. The optical semiconductor device according to claim 2, wherein a first groove is formed between the waveguide and the first terrace and a second groove is formed between the waveguide and the second terrace in the semiconductor layer of the optical modulator,
the first electrode is connected to the first conductivity type layer at a bottom portion of the first groove,
the second electrode is connected to the second conductivity type layer at an upper portion of the waveguide and connected to the second pad through the first groove,
the first conductivity type layer is removed in the first terrace and the second terrace of the optical modulator, and
a depth of the first groove at a connection portion between the first electrode and the first conductivity type layer, a depth of the first groove in a portion through which the second electrode passes, and a depth of the second groove are the same.
